(19) United States
(12) Patent Application Publication
(10) Pub. No.: US 2024/0264009 A1
(43) Pub. Date: Aug. 8, 2024

(54) SEMICONDUCTOR MANUFACTURING APPARATUS AND SEMICONDUCTOR DEVICE MANUFACTURING METHOD

(71) Applicant: Kioxia Corporation, Tokyo (JP)

(72) Inventors: Ai FURUBAYASHI, Yokohama Kanagawa (JP); Takaki HASHIMOTO, Yokohama Kanagawa (JP); Yenting KUO, Yokohama Kanagawa (JP)

(73) Assignee: Kioxia Corporation, Tokyo (JP)

(21) Appl. No.: 18/432,275

(22) Filed: Feb. 5, 2024

(30) Foreign Application Priority Data
Feb. 6, 2023 (JP) 2023-016305

(51) Int. Cl. G01K 11/125; H01L 21/66; H01L 21/67

(52) U.S. Cl. CPC G01K 11/125; H01L 21/67248; H01L 21/67253; H01L 22/12; H01L 22/26

(57) ABSTRACT

An apparatus includes a stage supporting a substrate with a material film on a first face from a second face side of the substrate. A light source generates a light beam. An optical system radiates the light beam to the substrate from the second face side. A detector detects a reflected light beam reflected from the substrate or the material film. A storage part stores therein reference spectrum waveforms generated in advance for shape parameters of the substrate or the material film with regard to the reflected light beam. An operation part compares a measured spectrum waveform obtained from an interference spectrum of the reflected light beam measured by the detector when the light beam is radiated with each of the reference spectrum waveforms to obtain a similar reference spectrum waveform that is one of the reference spectrum waveforms which is similar to the measured spectrum waveform.

### CROSS REFERENCE TO RELATED APPLICATIONS

This application is based upon and claims the benefit of priority from the prior Japanese Patent Application No. 2023-016305, filed on Feb. 6, 2023, the entire contents of which are incorporated herein by reference.

### FIELD

The embodiments of the present invention relate to a semiconductor manufacturing apparatus and a semiconductor device manufacturing method.

### BACKGROUND

In a process of processing a semiconductor wafer, such as an etching process, the temperature of the semiconductor wafer or the etched amount of a processed material may be measured in a contactless manner by means of a low-coherence interferometer or the like.

However, when the shape of the processed material is changed due to etching, accurate measurement of the temperature of the semiconductor wafer is difficult because of the influence of light reflected not only from a substrate but also from the processed material. Further, it is difficult to accurately determine the etched amount or the end of etching because of change in a light intensity signal immediately before the end of etching or ambient light from plasma.

### BRIEF DESCRIPTION OF THE DRAWINGS

FIG. 1 is a block diagram illustrating a configuration example of a semiconductor manufacturing apparatus according to a first embodiment;

FIG. 2 is a conceptual diagram illustrating an OPL in a case where a processed material is only a substrate;

FIG. 3 is a graph illustrating a spectrum waveform obtained in a case where a processed material is only a substrate;

FIG. 4 is a conceptual diagram illustrating an OPL in a case where a processed material is a substrate and a material film;

FIG. 5 is a graph illustrating a spectrum waveform obtained in a case where a processed material is a substrate and a material film;

FIG. 6 is a flowchart illustrating an example of a method of measuring the temperature of a substrate or a material film and a method of specifying a shape parameter according to the first embodiment;

FIG. 7A is a conceptual diagram illustrating a process of comparing a measured spectrum waveform with reference spectrum waveforms to obtain a similar reference spectrum waveform;

FIG. 7B is a conceptual diagram illustrating the process of comparing a measured spectrum waveform with reference spectrum waveforms to obtain a similar reference spectrum waveform;

FIG. 7C is a conceptual diagram illustrating the process of comparing a measured spectrum waveform with reference spectrum waveforms to obtain a similar reference spectrum waveform;

FIG. 8 is a graph illustrating a relation between a shift amount and a temperature change amount;

FIG. 9 is a cross-sectional view illustrating an example of a processed material;

FIG. 10A is a graph illustrating a spectrum waveform when the depth of a memory hole is 0%;

FIG. 10B is a graph illustrating a spectrum waveform when the depth of the memory hole is 20%;

FIG. 10C is a graph illustrating a spectrum waveform when the depth of the memory hole is 40%;

FIG. 10D is a graph illustrating a spectrum waveform when the depth of the memory hole is 60%;

FIG. 10E is a graph illustrating a spectrum waveform when the depth of the memory hole is 80%;

FIG. 10F is a graph illustrating a spectrum waveform when the depth of the memory hole is 100%;

FIG. 11 is a flowchart illustrating an example of a method of measuring the temperature of a substrate or a material film and a method of specifying a shape parameter according to a second embodiment;

FIG. 12A is a conceptual diagram illustrating a process of comparing a linked measured spectrum waveform with linked reference spectrum waveforms to obtain a similar reference spectrum waveform;

FIG. 12B is a conceptual diagram illustrating the process of comparing a linked measured spectrum waveform with linked reference spectrum waveforms to obtain a similar reference spectrum waveform;

FIG. 12C is a conceptual diagram illustrating the process of comparing a linked measured spectrum waveform with linked reference spectrum waveforms to obtain a similar reference spectrum waveform;

FIG. 13 is a diagram illustrating a first modification of the second embodiment;

FIG. 14 is a diagram illustrating the first modification of the second embodiment;

FIG. 15 is a diagram illustrating the first modification of the second embodiment;

FIG. 16 is a plan view illustrating a method of obtaining the film thickness (hole depth) of a substrate or a material film according to a second modification; and

FIG. 17 is a plan view illustrating the method of obtaining the film thickness (hole depth) of a substrate or a material film according to the second modification.

### DETAILED DESCRIPTION

A semiconductor manufacturing apparatus according to the present embodiment comprises a stage configured to support a substrate with a material film on a first face from a second face side of the substrate opposite to the first face. A light source is configured to generate a light beam. An optical system is configured to radiate the light beam to the substrate from the second face side. A detector is configured to detect a reflected light beam reflected from the substrate or the material film. A storage part is configured to store therein a plurality of reference spectrum waveforms respectively generated in advance for a plurality of shape parameters of the substrate or the material film with regard to the reflected light beam. An operation part is configured to compare a measured spectrum waveform obtained from an interference spectrum of the reflected light beam measured by the detector when the light beam is radiated with each of the reference spectrum waveforms to obtain a similar reference spectrum waveform that is one of the reference spectrum waveforms which is similar to the measured spectrum waveform. Hereinafter, apparatuses of the present disclosure will be described with reference to the drawings.

The present invention is not limited to the embodiments. In the present specification and the drawings, elements identical to those described in the foregoing drawings are denoted by like reference characters and detailed explanations thereof are omitted as appropriate.

### First Embodiment

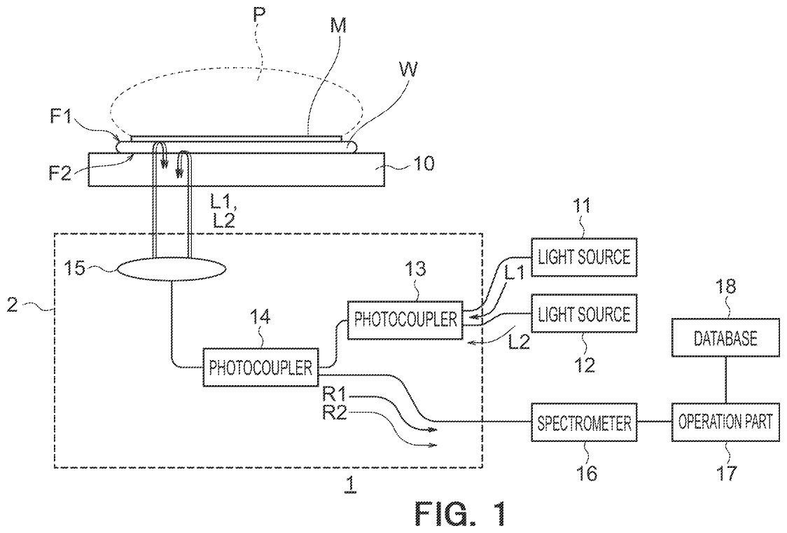

FIG. 1 is a block diagram illustrating a configuration example of a semiconductor manufacturing apparatus 1 according to a first embodiment. The semiconductor manufacturing apparatus 1 may bean etching device, a film deposition device, a heat treatment device, or the like. The semiconductor manufacturing apparatus 1 includes a stage 10, light sources 11 and 12, photocouplers 13 and 14, a collimator lens 15, a spectrometer 16, an operation part 17, and a database (a storage part) 18.

The stage 10 may be a wafer stage using an ESC (Electrostatic Chuck) that supports and absorbs the substrate (semiconductor wafer) W in an electrostatic manner. The substrate W has a material film M on a first face F1 thereof, and a second face F2 opposite to the first face F1 faces the stage 10. The stage 10 supports the substrate W from the second face F2 side. The stage 10 is made of a material that allows light beams L1 and L2 to pass therethrough. For example, a window is provided in the stage 10 at a position through which the light beams L1 and L2 pass. The window is made of a material allowing the light beams L1 and L2 to pass therethrough.

The light source 11 generates the light beam L1 having a first wavelength. The light source 12 generates the light beam L2 having a second wavelength different from the first wavelength. The light beams L1 and L2 are radiated from the second face F2 side of the substrate W through an optical system 2 and the stage 10.

The optical system 2 radiates the light beams L1 and L2 from the light sources 11 and 12 onto the substrate W or the material film M. Further, the optical system 2 sends reflected light beams R1 and R2 reflected from the substrate W or the material film M to the spectrometer 16. The optical system 2 includes, for example, the photocouplers 13 and 14 and the collimator lens 15. The photocoupler 13 sends the light beams L1 and L2 to the photocoupler 14. The photocoupler 14 radiates the light beams L1 and L2 onto the substrate W or the material film M through the collimator lens 15. When the light beams L1 and L2 are reflected from the substrate W or the material film M, the reflected light beams R1 and R2 are incident on the photocoupler 14 through the collimator lens 15. The reflected light beams R1 and R2 are then sent from the photocoupler 14 to the spectrometer 16.

The spectrometer 16 detects the intensity of the reflected light beams R1 and R2 reflected from the substrate W or the material film M. For example, the spectrometer 16 measures the intensity of the reflected light beams R1 and R2 at each frequency and sends the measurement result (an interference spectrum) to the operation part 17.

The operation part 17 performs Fourier transform of the interference spectrum of the reflected light beams R1 and R2 and normalizes them. With this configuration, the operation part 17 generates a signal intensity waveform (a spectrum waveform) for an optical path length (OPL) of the light beams L1 and L2.

The OPL corresponding to a peak of this spectrum waveform depends on the thickness of the substrate W or the material film M and the refractive index thereof. Therefore, when thermal expansion or thermal contraction of the substrate W or the material film M occurs due to the temperature and the refractive index of the substrate W or the material film M changes, the operation part 17 can calculate the temperature change of the substrate W or the material film M by using the OPL.

In addition, the operation part 17 compares the generated spectrum waveform of the substrate W or the material film M as a processed material with a plurality of reference spectrum waveforms stored in the database 18. A spectrum waveform obtained by measuring the processed material is hereinafter referred to as “measured spectrum waveform”. Further, a spectrum waveform stored in the database 18 in advance and used as a criterion of comparison with the measured spectrum waveform is hereinafter referred to as “reference spectrum waveform”. The operation part 17 obtains the most similar one of the reference spectrum waveforms to the measured spectrum waveform. The reference spectrum waveform that is the most similar to the measured spectrum waveform is hereinafter referred to as “similar reference spectrum waveform”. Calculation of similarity between the reference spectrum waveform and the measured spectrum waveform will be described later.

The database 18 stores therein a plurality of reference spectrum waveforms generated in advance for a plurality of shape parameters of the substrate W or the material film M with regard to the reflected light beams R1 and R2. The shape parameters are parameters related to the shape of the substrate W or the material film M and affecting spectrum waveforms. For example, as described above, the shape parameters may be any of the thicknesses of the substrate W or the material film M, the depths of a hole formed in the substrate W or the material film M (etched amounts), or the diameters of the hole.

The reference spectrum waveforms are generated in advance by actual measurement, simulation, or the like for various shape parameters and stored in the database 18, before measurement of the interference spectrum of the processed material. Therefore, the reference spectrum waveforms include the influences of reflected light beams not only from the substrate W but also from the material film M. When the shape parameter corresponding to a reference spectrum waveform matches the shape parameter of the substrate W or the material film M in the measurement of the interference spectrum, the measured spectrum waveform is substantially coincident with or similar to that reference spectrum waveform. That is, according to the present embodiment, the shape parameter of the substrate W or the material film M can be determined, also considering the influence of the reflected light beam from the material film M.

The reference spectrum waveforms are generated for various shape parameters and are discrete. Therefore, a reference spectrum waveform between adjacent shape parameters may be interpolated by using a regression model. With this configuration, the reference spectrum waveforms can be generated for continuous shape parameters.

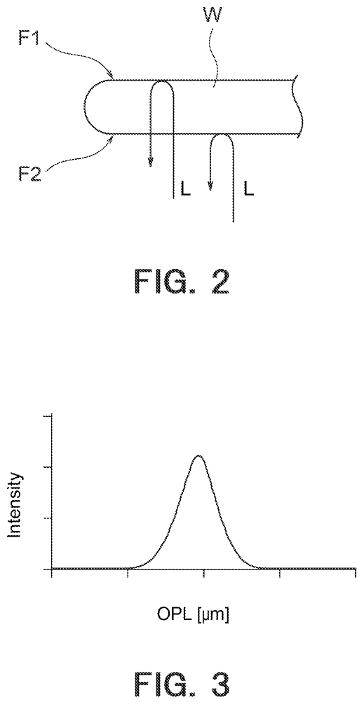

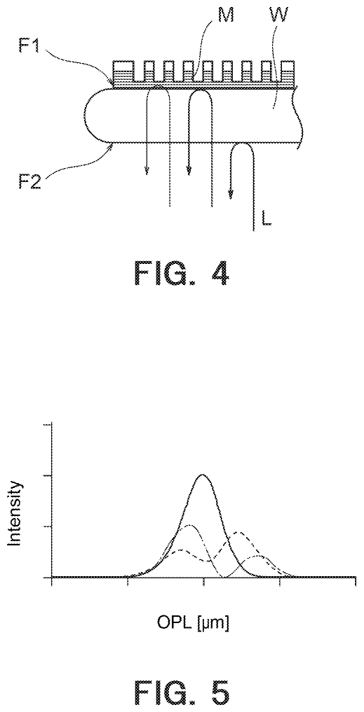

FIG. 2 is a conceptual diagram illustrating the OPL in a case where a processed material is only the substrate W. FIG. 3 is a graph illustrating a spectrum waveform obtained in a case where the processed material is only the substrate W. As illustrated in FIG. 2, in a case where only the substrate W is a processed material, a light beam L is reflected from the first face F1 and the second face F2 of the substrate W. Therefore, as illustrated in FIG. 3, a spectrum waveform obtained by interference between the reflected light beams from the substrate W has a clear peak. In this case, the operation part 17 can relatively accurately calculate the temperature of the substrate W or the material film M by using a change of the OPL.

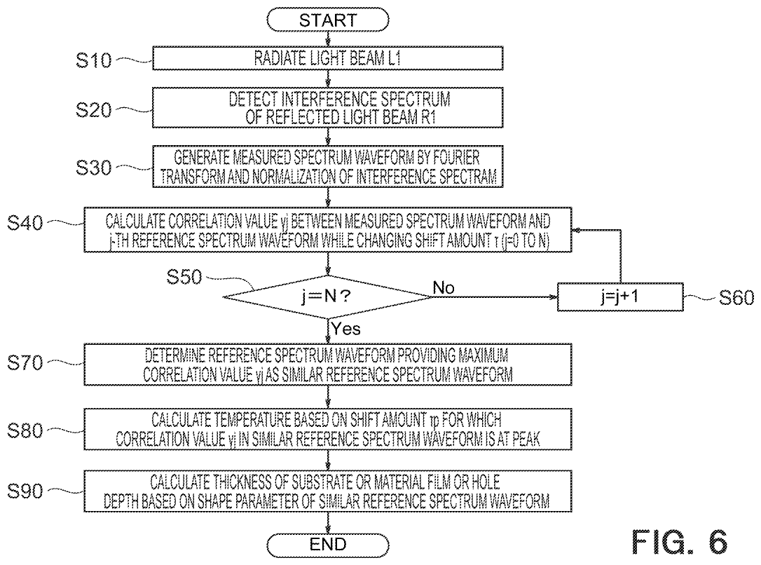

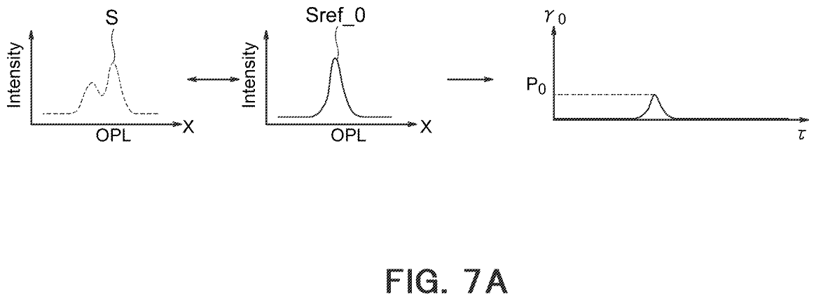

Meanwhile, FIG. 4 is a conceptual diagram illustrating the OPL in a case where a processed material is the substrate W and the material film M. FIG. 5 is a graph illustrating a spectrum waveform obtained in a case where the processed material is the substrate W and the material film M. As illustrated in FIG. 4, in a case where the material film M is provided on the substrate W, the light beam L is reflected not only from the first face F1 and the second face F2 of the substrate W but also from front and back faces of the material film M. Further, in a case where the material film M is a multilayer film, the light beam is also reflected from each interface in the multilayer film. Therefore, as illustrated in FIG. 5, specifying a peak of a spectrum waveform obtained by interference between the reflected light beams from the substrate W and the material film M becomes relatively difficult, and the OPL may include an error. In this case, it is difficult to relatively accurately calculate the temperature of the substrate W or the material film M by using the change in the OPL.

Accordingly, the semiconductor manufacturing apparatus 1 according to the present embodiment calculates or measures reference spectrum waveforms in advance for various shape parameters of the substrate W or the material film M with regard to the reflected light beams R1 and R2 and stores these reference spectrum waveforms in the database 18. The operation part 17 compares a measured spectrum waveform with the reference spectrum waveforms stored in the database 18 to obtain a similar reference spectrum waveform that is the most similar to the measured spectrum waveform. With this configuration, it is possible to specify the shape parameter of the substrate W or the material film M or calculate the temperature, also considering the influence of the reflected light beam from the material film M. Specifying the shape parameter and calculation of the temperature will be described later.

Next, a method of specifying the shape parameter of a processed material and a method of measuring the temperature of the processed material are described, where both methods use the semiconductor manufacturing apparatus 1.

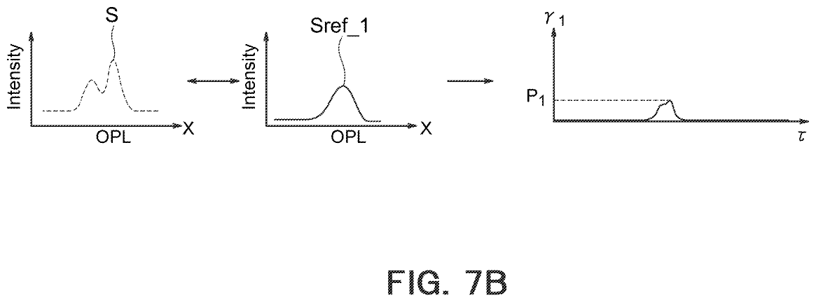

FIG. 6 is a flowchart illustrating an example of a method of measuring the temperature of the substrate W or the material film M and the method of specifying the shape parameter according to the first embodiment. Here, an etching process using a cryogenic etching device is described as an example. However, the present embodiment can also be applied to other processes, such as a film deposition process and a heat treatment process. Further, the present embodiment can also be applied to a case where a processed material is only the substrate W. Although the light source 11 is used in the first embodiment, the light beam L2 may be used in place of the light beam L1. When the light beam L1 is used, the light source 12 may be omitted. When the light beam L2 is used, the light source 11 may be omitted.

The substrate W with the material film M formed on the first face F1 is placed on the stage 10. The substrate W is placed with the second face F2 facing the stage 10. The stage 10 absorbs the substrate W by electrostatic absorption.

Subsequently, the light source 11 generates the light beam L1. The optical system 2 radiates the light beam L1 from the second face F2 side of the substrate W (S10). The spectrometer 16 detects the reflected light beam R1 reflected from the substrate W or the material film M (S20). By detecting the reflected light beam R1 of the light beam L1 radiated from the second face F2 side of the substrate W in this manner, an interference spectrum of the light intensity at each frequency of the reflected light beam R1 is measured without being influenced by ambient light from plasma P.

Subsequently, the operation part 17 performs Fourier transform of the interference spectrum of the reflected light beam R1 and further performs normalization, thereby generating a measured spectrum waveform (S30).

The operation part 17 then compares the measured spectrum waveform with each of reference spectrum waveforms generated in advance for shape parameters of the substrate W or the material film M with regard to the reflected light beam R1. Thereafter, the operation part 17 obtains a similar reference spectrum waveform that is the most similar one of the reference spectrum waveforms to the measured spectrum waveform. Calculation of the similar reference spectrum waveform is described below.

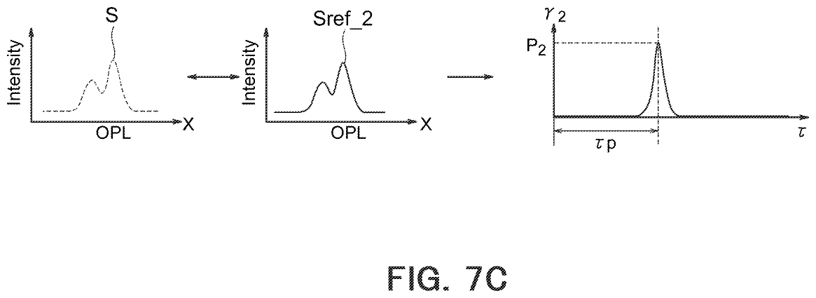

FIGS. 7A to 7C are conceptual diagrams illustrating a process of comparing a measured spectrum waveform with reference spectrum waveforms to obtain a similar reference spectrum waveform. A measured spectrum waveform S is the same in FIGS. 7A to 7C. Reference spectrum waveforms Sref_0, Sref_1, and Sref_2 in FIGS. 7A to 7C are spectrum waveforms acquired for different shape parameters, respectively. Although three reference spectrum waveforms that are different from each other in shape parameter are used in the present embodiment, N (N is a positive integer) reference spectrum waveforms that are different from each other in shape parameter may be used, where N is four or more.

The operation part 17 compares the measured spectrum waveform S with each of the reference spectrum waveforms Sref_0, Sref_1, and Sref_2 and performs fitting.

For example, when fitting between the measured spectrum waveform S and the reference spectrum waveform Sref_0 is performed, the operation part 17 calculates a correlation value γⱼ(T) in Expression 1 while shifting the measured spectrum waveform S and the reference spectrum waveform Sref_0 in the x-axis direction relative to each other (while changing the shift amount T) (S40). At this time, the operation part 17 calculates Expression 1 with regard to the light intensity I(x) of the measured spectrum waveform S and the light intensity T₀(x) of the reference spectrum waveform Sref_0.

$$\begin{matrix}[ Expression 1 ] & \\ {γ}_{j} ( τ ) = \int I ( x - τ ) {T}_{j} ( x ) dx & ( Expression 1 )\end{matrix}$$

Here, x is the optical path length OPL of the light beam L1, and T is the amount of relative shift of the optical path length OPL (in the x-axis direction) between the measured spectrum waveform S and the reference spectrum waveform Sref_0. The shift amount T may be shifted in either the +x-direction or the −x-direction. In addition, j is an identifier of the reference spectrum waveform Sref_0. For example, j is 0 to N. The identifier j of the reference spectrum waveform Sref_0 is 0.

The operation part 17 initially calculates a correlation value γ₀(0) for the shift amount T being 0. The correlation value γ₀(0) is a value when τ=0 in the right graph in FIG. 7A. Similarly, the operation part 17 calculates the correlation value γ₀(τ) while shifting in the +x-direction and the −x-direction by the shift amount τ, thereby obtaining the right graph in FIG. 7A. At this time, the maximum peak of the correlation value γ₀(τ) is P₀.

Subsequently, when the identifier j has not reached N (No at S50), the operation part 17 increments j by 1 (j=j+1) (S60). The operation part 17 then repeats Step S40. That is, the operation part 17 compares the measured spectrum waveform S with the reference spectrum waveform Sref_1 and performs fitting.

When fitting between the measured spectrum waveform S and the reference spectrum waveform Sref_1 is performed, the operation part 17 calculates a correlation value γ₁(T) in Expression 1 while shifting the measured spectrum waveform S and the reference spectrum waveform Sref_1 in the x-axis direction relative to each other. The identifier j of the reference spectrum waveform Sref_1 is 1. At this time, the operation part 17 calculates Expression 1 with regard to the light intensity I(x) of the measured spectrum waveform S and the light intensity T₁(x) of the reference spectrum waveform Sref_1. The operation part 17 calculates the correlation value γ₁(τ) while shifting in the +x-direction and the −x-direction by the shift amount τ, thereby obtaining the right graph in FIG. 7B. At this time, the maximum peak of the correlation value γ₁(τ) is P₁.

Subsequently, when the identifier j has not reached N (No at S50), the operation part 17 further increments j by 1 (j=j+1) (S60). The operation part 17 then repeats Step S40. That is, the operation part 17 compares the measured spectrum waveform S with the reference spectrum waveform Sref_2 and performs fitting.

When fitting between the measured spectrum waveform S and the reference spectrum waveform Sref_2 is performed, the operation part 17 calculates a correlation value γ₂(τ) in Expression 1 while shifting the measured spectrum waveform S and the reference spectrum waveform Sref_2 in the x-axis direction relative to each other. The identifier j of the reference spectrum waveform Sref_2 is 2. At this time, the operation part 17 calculates Expression 1 with regard to the light intensity I(x) of the measured spectrum waveform S and the light intensity T₂(x) of the reference spectrum waveform Sref_2. The operation part 17 calculates the correlation value γ₂(τ) while shifting in the +x-direction and the −x-direction by the shift amount τ, thereby obtaining the right graph in FIG. 7C. At this time, the maximum peak of the correlation value γ₂(T) is P₂.

When there are N reference spectrum waveforms, Steps S40 to S60 are repeated until the identifier j reaches N.

When the identifier j reaches N (for example, N=2) (Yes at S50), the operation part 17 sets the reference spectrum waveform Sref_2 among the reference spectrum waveforms Sref_0 to Sref_2, which has the largest correlation value γⱼ(T), as a similar reference spectrum waveform (S70). That is, the operation part 17 determines the reference spectrum waveform Sref_2 corresponding to the maximum peak P₂ among the peaks P₀ to P₂ as the similar reference spectrum waveform that has the highest similarity to the measured spectrum waveform S.

Subsequently, the operation part 17 calculates the temperature of the substrate W or the material film M based on a shift amount τp for which the correlation value γ₂(T) of the similar reference spectrum waveform Sref_2 is the peak P₂ (S80).

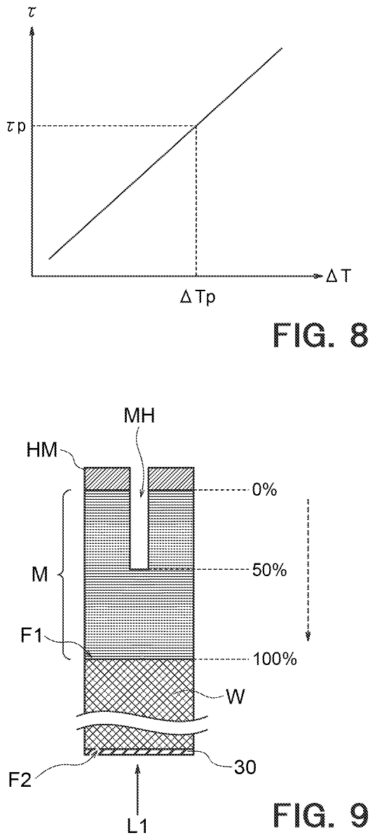

FIG. 8 is a graph illustrating a relation between the shift amount τ and a temperature change amount ΔT. The database 18 stores therein a relational expression that represents the relation between the shift amount τ and the temperature change amount ΔT illustrated in FIG. 8, in advance. The operation part 17 calculates the temperature change amount ΔTp corresponding to the shift amount τp of the similar reference spectrum waveform Sref_2 by using the relation between the shift amount T and the temperature change amount ΔT. Assuming that the temperature at the time of generation of a reference spectrum waveform, for example, a set temperature at the time of calculation of the reference spectrum waveform by simulation performed in advance is T_{I}, the temperature of the substrate W or the material film M is represented by T_{I}+ΔTp. The operation part 17 calculates the temperature T_{I}+ΔTp of the substrate W or the material film M, thereby obtaining the temperature of the substrate W or the material film M. In a case where the reference spectrum waveform is generated by actual measurement, as for the set temperature T_{I}, the temperature at the time of generation of the reference spectrum waveform may be measured, and the obtained temperature information may be stored in the database 18. Further, as for the relation between the shift amount T and the temperature change amount ΔT in FIG. 8, spectrum waveforms of the substrate W or the material film M may be acquired while changing the temperature, and the relational expression between the temperature change amount ΔT and the shift amount τ may be stored in the database 18 in advance. The relational expression between the temperature change amount ΔT and the shift amount τ is substantially unchanged by shape parameters. Therefore, the graph in FIG. 8 can be applied to the substrates W or the material films M having various shape parameters.

The similar reference spectrum waveform Sref_2 has high similarity to the measured spectrum waveform S in waveform shape. Therefore, the shape parameter corresponding to the similar reference spectrum waveform Sref_2 substantially matches or is similar to the shape parameter of the substrate W or the material film M in the measurement of the measured spectrum waveform S. For example, the thickness of the substrate W or the material film M during etching substantially matches or is close to the thickness of the shape parameter corresponding to the similar reference spectrum waveform Sref_2. Accordingly, the operation part 17 can specify the thickness of the substrate W or the material film M during etching from the shape parameter of the similar reference spectrum waveform Sref_2. When the thickness of the substrate W or the material film M is found, the operation part 17 can calculate the depth of etching, such as the hole depth, by subtracting the thickness of the substrate W or the material film M during etching from the initial thickness of the substrate M or the material film M (S90). Alternatively, the depths of etching may be stored as shape parameters in the database 18 in advance in association with reference spectrum waveforms. In this case, the operation part 17 can directly specify the depth of etching from the shape parameter corresponding to the similar reference spectrum waveform Sref_2.

As described above, according to the present embodiment, the operation part 17 compares the measured spectrum waveform S of the reflected light beam R1 with each of the reference spectrum waveforms Sref_0 to Sref_2 to obtain the similar reference spectrum waveform Sref_2 that is the most similar to the measured spectrum waveform S. The operation part 17 can calculate the temperature T (T₀+ΔTp) of the substrate W or the material film M based on the relative shift amount τp between the measured spectrum waveform S and the similar reference spectrum waveform Sref_2, for which the correlation value γⱼ(T) becomes the peak P₂. Further, the operation part 17 can specify a shape parameter with regard to the substrate W or the material film M based on the shape parameter corresponding to the similar reference spectrum waveform Sref_2. The operation part 17 can calculate, for example, the hole depth by using this shape parameter.

The temperature T₀+ΔTp of the substrate W or the material film M and the shape parameter of the substrate W or the material film M can be calculated in real time during etching of the substrate W or the material film M.

According to the present embodiment, reference spectrum waveforms are generated, considering various shape parameters of the substrate W or the material film M. Therefore, the semiconductor manufacturing apparatus 1 can accurately measure the temperature of the substrate W or the material film M or the etched amount of the substrate W or the material film M, considering the shape parameter, not only in a case where only the substrate W is to be processed but also in a case where the material film M is provided on the substrate W.

In Expression 1 described above, the measured spectrum waveform S is shifted by the shift amount T relative to the reference spectrum waveforms Sref_0 to Sref_2. However, as represented by Expression 2, the reference spectrum waveforms Sref_0 to Sref_2 may be shifted by the shift amount T relative to the measured spectrum waveform S. The advantageous effects of the present embodiment can also be obtained by using Expression 2.

$$\begin{matrix}[ Expression 2 ] & \\ {γ}_{i} ( τ ) = \int I ( x ) {T}_{j} ( x - τ ) dx & ( Expression 2 )\end{matrix}$$

### Second Embodiment

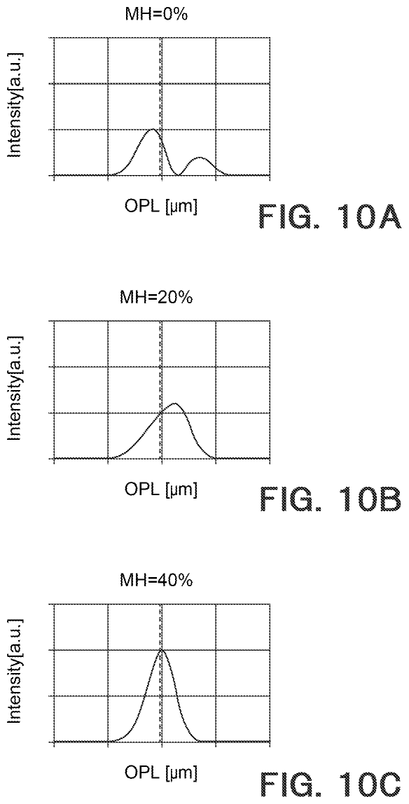

FIG. 9 is a cross-sectional view illustrating an example of a processed material. The processed material includes, for example, the substrate W and the material film M. A nitride film 30 as an anti-reflection film is provided on the second face F2 of the substrate W. The material film M has, for example, a multilayer structure of silicon oxide films and silicon nitride films. A hard mask HM is provided on the material film M. In a second embodiment, a memory hole MH is formed in the material film M by using the hard mask HM as mask. The memory hole MH is formed to penetrate through the multilayer structure of the material film M from the upper layer to the lower layer and reach the substrate W.

In FIG. 9, the depth of the memory hole MH is represented by numerical percentage, assuming that the top face of the material film M that has not been etched is 0% and the state where the memory hole MH has reached the substrate W is 100%.

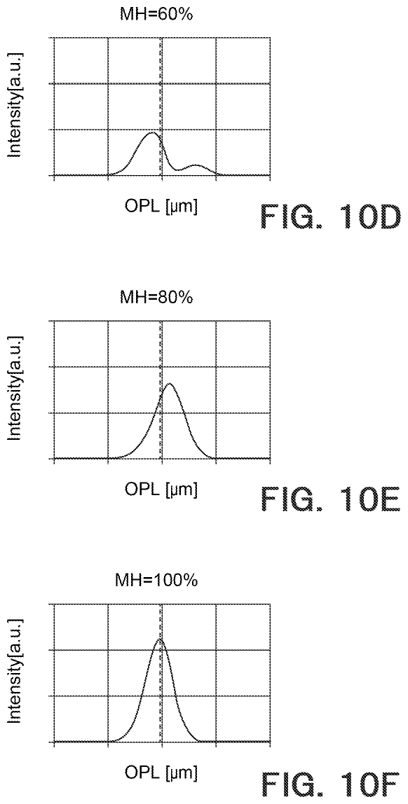

FIGS. 10A to 10F are graphs illustrating spectrum waveforms when the depth of the memory hole MH in FIG. 9 is 0% to 100%.

As etching progresses from 0% to 100%, the optical path length OPL of the light beam L1 gradually changes. Accordingly, the spectrum waveform periodically has a peak, depending on the wavelength of the light beam L1. For example, when the depth of the memory hole MH is 0% to 40% as illustrated in FIGS. 10A to 10C, the peak of the spectrum waveform gradually becomes higher. When the depth of the memory hole MH is 40%, the spectrum waveform has the highest peak due to interference of the light beam L1. When the depth of the memory hole MH is 60% to 100% as illustrated in FIGS. 10D to 10F, the peak of the spectrum waveform gradually becomes higher. When the depth of the memory hole MH is 100%, the spectrum waveform has the highest peak due to interference of the light beam L1. As described above, as etching progresses from 0% to 100%, the peak of the spectrum waveform may become higher and lower periodically.

As illustrated in FIGS. 10C and 10F, the spectrum waveforms may be similar to each other despite the fact that the depths of the memory hole MH are different from each other. In this case, there is a risk that specifying a similar reference spectrum waveform becomes difficult. For example, when the measured spectrum waveform S is the spectrum waveform for a case where the depth of the memory hole MH is 40%, there is a risk that the operation part 17 incorrectly determines the reference spectrum waveform for a case where the depth of the memory hole MH is 100% as the similar reference spectrum waveform.

For this reason, in the second embodiment, a measured spectrum waveform and reference spectrum waveforms are generated by using not only the light beam L1 but also the light beam L2 with the second wavelength different from the first wavelength of the light beam L1. Use of the measured spectrum waveform and the reference spectrum waveforms of each of the light beams L1 and L2 different from each other in wavelength enables the operation part 17 to specify a correct similar reference spectrum waveform. The second embodiment is described below in detail.

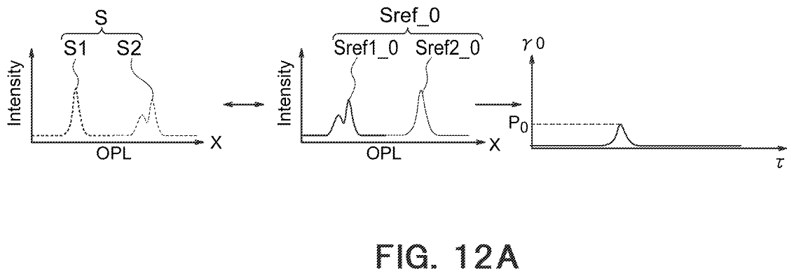

In the second embodiment, reference spectrum waveforms are generated by linking a first spectrum waveform Sref1_j and a second spectrum waveform Sref2_j together, as represented by Sref_0 to Sref_2 in FIGS. 12A to 12C. The first spectrum waveform Sref1_j is a reference spectrum waveform generated in advance for a shape parameter of the substrate W or the material film M with regard to the reflected light beam R1. The second spectrum waveform Sref2_j is a reference spectrum waveform generated in advance for a shape parameter of the substrate W or the material film M with regard to the reflected light beam R2. The spectrum waveforms Sref1_j and Sref2_j linked together are both generated to correspond to the substrate W or the material film M that has the same shape parameter. The method of linking the spectrum waveforms Sref1_j and Sref2_j together is not specifically limited to any form. For example, those waveforms may be linked together in such a manner that the maximum value of the OPL of the spectrum waveform Sref1_j and the minimum value of the OPL of the spectrum waveform Sref2_j are continuous with each other. The method of linking spectrum waveforms is the same and unified for all linked reference spectrum waveforms. The reference spectrum waveform generated by linking the first and second spectrum waveforms Sref1_j and Sref2_j together is hereinafter referred to as “linked reference spectrum waveform”.

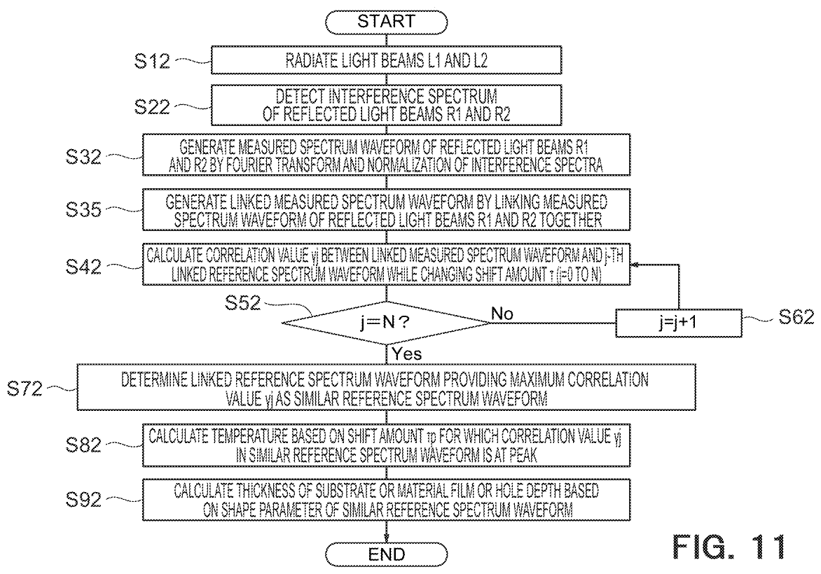

FIG. 11 is a flowchart illustrating an example of a method of measuring the temperature of the substrate W or the material film M and a method of specifying a shape parameter according to the second embodiment.

The substrate W with the material film M formed on the first face F1 is placed on the stage 10, similarly to the first embodiment.

Subsequently, the light source 11 generates the light beam L1, and the light source 12 generates the light beam L2. The optical system 2 radiates the light beams L1 and L2 from the second face F2 side of the substrate W (S12). As described later, the light beams L1 and L2 may be radiated to the same position at the same time or may be radiated at different times or to different positions. The spectrometer 16 detects the reflected light beams R1 and R2 reflected from the substrate W or the material film M (S22). Accordingly, interference spectram of the light intensity at each frequency of the reflected light beams R1 and R2 are measured, respectively.

Subsequently, the operation part 17 performs Fourier transform of the interference spectra of the reflected light beams R1 and R2 and further performs normalization, thereby generating a measured spectrum waveform of each of the reflected light beams R1 and R2 (S32).

The operation part 17 then links the measured spectrum waveform of the reflected light beam R1 and the measured spectrum waveform of the reflected light beam R2 together to generate a linked measured spectrum waveform S (S35). The measured spectrum waveforms are linked together in the same way as the method of linking the reference spectrum waveforms together. That is, linking is performed in such a manner that the maximum value of the OPL of a measured spectrum waveform S1 and the minimum value of the OPL of a spectrum waveform S2 are continuous with each other. Consequently, the linked measured spectrum waveform becomes comparable with the linked reference spectrum waveforms.

Subsequently, the operation part 17 compares the linked measured spectrum waveform S with each of the linked reference spectrum waveforms Sref_0, Sref_1, and Sref_2 and performs fitting. A method of fitting between the linked measured spectrum waveform S and the linked reference spectrum waveforms Sref_0, Sref_1, and Sref_2 may be the same as the method of fitting between the measured spectrum waveform S and the reference spectrum waveforms Sref_0, Sref_1, and Sref_2 in the first embodiment.

FIGS. 12A to 12C are conceptual diagrams illustrating a process of comparing a linked measured spectrum waveform with linked reference spectrum waveforms to obtain a similar reference spectrum waveform. The linked measured spectrum waveform S is the same in FIGS. 12A to 12C. The linked reference spectrum waveforms Sref_0, Sref_1, and Sref_2 in FIGS. 12A to 12C are spectrum waveforms acquired for different shape parameters, respectively. Although three linked reference spectrum waveforms that are different from each other in shape parameter are used in the present embodiment, N linked reference spectrum waveforms that are different from each other in shape parameter may be used, N being four or more.

For example, when fitting between the linked measured spectrum waveform S and the linked reference spectrum waveform Sref_0 is performed, the operation part 17 calculates the correlation value γⱼ(T) in Expression 1 while shifting the linked measured spectrum waveform S and the linked reference spectrum waveform Sref_0 in the x-axis direction relative to each other (while changing the shift amount τ) (S42). At this time, the operation part 17 calculates Expression 1 with regard to the light intensity I(x) of the linked measured spectrum waveform S and the light intensity T₀(x) of the linked reference spectrum waveform Sref_0.

The operation part 17 calculates the correlation value γ₀(τ) while shifting in the +x-direction and the −x-direction by the shift amount τ, thereby obtaining the right graph in FIG. 12A. At this time, the peak of the correlation value γ₀(τ) is P₀.

Subsequently, when the identifier j has not reached N (No at S52), the operation part 17 increments j by 1 (j=j+1) (S62). The operation part 17 then repeats Step S42. That is, the operation part 17 compares the linked measured spectrum waveform S with the linked reference spectrum waveform Sref_1 and performs fitting.

When fitting between the linked measured spectrum waveform S and the linked reference spectrum waveform Sref_1 is performed, the operation part 17 calculates the correlation value γ₁(τ) in Expression 1 while shifting the linked measured spectrum waveform S and the linked reference spectrum waveform Sref_1 in the x-axis direction relative to each other. At this time, the operation part 17 calculates Expression 1 with regard to the light intensity I(x) of the linked measured spectrum waveform S and the light intensity T₁(x) of the linked reference spectrum waveform Sref_1.

The operation part 17 calculates the correlation value γ₁(τ) while shifting in the +x-direction and the −x-direction by the shift amount τ, thereby obtaining the right graph in FIG. 12B. The peak of the correlation value γ₁(τ) is P₁.

Subsequently, when the identifier j has not reached N (No at S52), the operation part 17 further increments j by 1 (j=j+1) (S62). The operation part 17 then repeats Step S42. That is, the operation part 17 compares the linked measured spectrum waveform S with the linked reference spectrum waveform Sref_2 and performs fitting.

When fitting between the linked measured spectrum waveform S and the linked reference spectrum waveform Sref_2 is performed, the operation part 17 calculates the correlation value γ₂(τ) in Expression 1 while shifting the linked measured spectrum waveform S and the linked reference spectrum waveform Sref_2 in the x-axis direction relative to each other. At this time, the operation part 17 calculates Expression 1 with regard to the light intensity I(x) of the linked measured spectrum waveform S and the light intensity T₂(x) of the linked reference spectrum waveform Sref_2. The operation part 17 calculates the correlation value r₂(τ) while shifting in the +x-direction and the −x-direction by the shift amount τ, thereby obtaining the right graph in FIG. 12C. At this time, the peak of the correlation value γ₂(τ) is P₂.

When there are N linked reference spectrum waveforms, Steps S42 to S62 are repeated until the identifier j reaches N.

When the identifier j reaches N (for example, N=2) (Yes at S52), the operation part 17 sets the linked reference spectrum waveform Sref_2 among the linked reference spectrum waveforms Sref_0 to Sref_2, which has the largest correlation value γⱼ(τ), as a similar reference spectrum waveform (S72). That is, the operation part 17 determines the linked reference spectrum waveform Sref_2 corresponding to the maximum peak P₂ among the peaks P₀ to P₂ as the similar reference spectrum waveform that has the highest similarity to the linked measured spectrum waveform S.

Subsequently, the operation part 17 calculates the temperature of the substrate W or the material film M based on a shift amount τp for which the correlation value γ₂(τ) of the similar reference spectrum waveform Sref_2 becomes the peak P₂ (S82). The method of calculating the temperature of the substrate W or the material film M is as described with reference to FIG. 8.

Further, the similar reference spectrum waveform Sref_2 has high similarity to the linked measured spectrum waveform S in waveform shape. Therefore, the shape parameter corresponding to the similar reference spectrum waveform Sref_2 substantially matches or is similar to the shape parameter of the linked measured spectrum waveform S. Accordingly, the operation part 17 can specify the thickness of the substrate W or the material film M during etching from the shape parameter of the similar reference spectrum waveform Sref_2. When the thickness of the substrate W or the material film M is found, the operation part 17 can calculate the depth of etching, such as the hole depth, by subtracting the thickness of the substrate W or the material film M during etching from the initial thickness of the substrate M or the material film M (S92).

According to the second embodiment, a linked measured spectrum waveform and linked reference spectrum waveforms are generated by using the light beams L1 and L2 different from each other in wavelength, and the linked measured spectrum waveform and the liked reference spectrum waveforms are compared with each other, thereby determining similarity therebetween. Therefore, specifying a similar reference spectrum waveform is more accurate and easier than in a case of specifying the similar reference spectrum waveform by using only the light beam L1.

For example, when the measured spectrum waveform S1 and the reference spectrum waveform Sref1_1 are compared with each other in FIG. 12B, they are similar to each other. Therefore, there is a risk that the operation part 17 determines the reference spectrum waveform Sref1_1 as the similar reference spectrum waveform incorrectly.

However, comparison between the linked measured spectrum waveform S obtained by linking the measured spectrum waveforms S1 and S2 together and the linked reference spectrum waveform Sref_1 obtained by linking the reference spectrum waveforms Sref1_1 and Sref2_1 together shows that they are not similar to each other. Therefore, the peak P₁ of the correlation value γ₁ becomes relatively low, and the operation part 17 does not determine the reference spectrum waveform Sref_1 as the similar reference spectrum waveform.

Meanwhile, in FIG. 12C, the measured spectrum waveform S1 and the reference spectrum waveform Sref1_2 are similar to each other, and the measured spectrum waveform S2 and the reference spectrum waveform Sref2_2 are also similar to each other. Therefore, the peak P₂ of the correlation value γ₂ becomes high, and the operation part 17 can correctly determine the linked reference spectrum waveform Sref_2 as the similar reference spectrum waveform.

Other configurations and operations of the second embodiment may be identical to corresponding configurations and operations of the first embodiment. Accordingly, the second embodiment can obtain identical effects as those of the first embodiment.

### (First Modification)

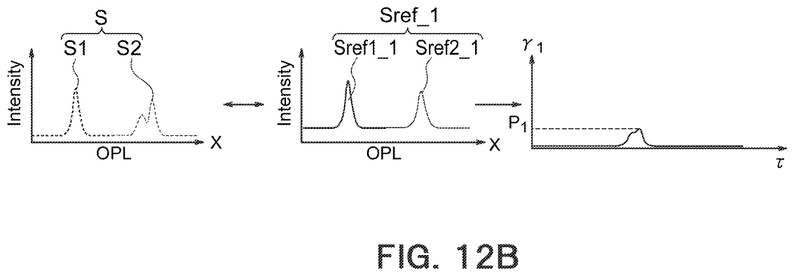

FIGS. 13 to 15 are diagrams illustrating a first modification of the second embodiment.

As illustrated in FIG. 13, the optical system 2 may radiate the light beams L1 and L2 to substantially the same position on the second face F2 of the substrate W. Further, the optical system 2 may radiate the light beams L1 and L2 to substantially the same position on the second face F2 of the substrate W at substantially the same time. Even when the light beams L1 and L2 are radiated to substantially the same position on the second face F2 of the substrate W at substantially the same time, the operation part 17 can acquire measured spectrum waveforms respectively corresponding to the light beams L1 and L2 by Fourier transform. The optical system 2 may radiate the light beams L1 and L2 to substantially the same position on the second face F2 of the substrate W at different times.

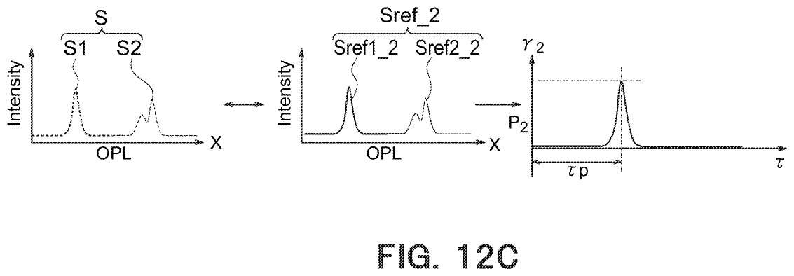

As illustrated in FIG. 14, the optical system 2 may radiate the light beams L1 and L2 to different positions on the second face F2 of the substrate W. Also in this case, the optical system 2 may radiate the light beams L1 and L2 at substantially the same time. In this case, the operation part 17 can acquire measured spectrum waveforms respectively corresponding to the light beams L1 and L2 while clearly distinguishing those waveforms from each other.

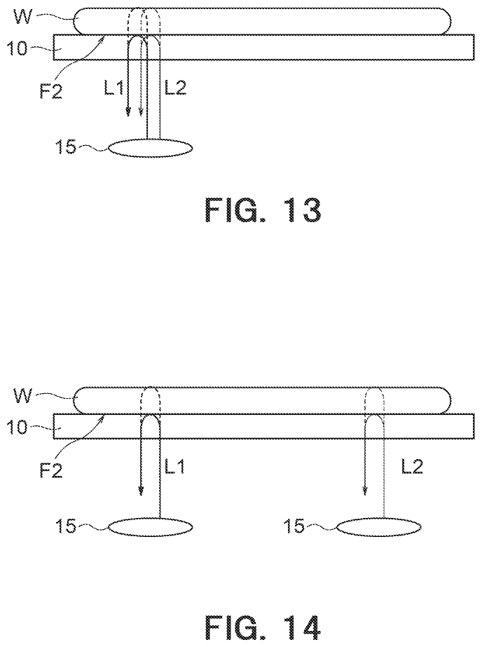

In FIG. 15, the light sources 11 and 12 generate the light beams L1 and L2 at different timings, respectively. For example, while the light source 11 generates the light beam L1, the light source 12 stops generation of the light beam L2. While the light source 12 generates the light beam L2, the light source 11 stops generation of the light beam L1.

In the present modification, a plurality of spectrometers 16_1 and 16_2 are provided. While the light source 11 generates the light beam L1, the spectrometer 16_1 detects the reflected light beam R1. While the light source 12 generates the light beam L2, the spectrometer 16_2 detects the reflected light beam R2. With this configuration, the reflected light beams R1 and R2 of the light beams L1 and L2 can reliably be detected separately from each other.

In the embodiments described above, the operation part 17 calculates both the temperature of the substrate W or the material film M and the thickness of (the hole depth in) the substrate W or the material film M. However, the operation part 17 may calculate either the temperature of the substrate W or the material film M or the thickness of (the hole depth in) the substrate W or the material film M. In this case, either Step S80 or S90 in FIG. 6 is omitted. Alternatively, either Step S82 or S92 in FIG. 11 is omitted.

### (Second Modification)

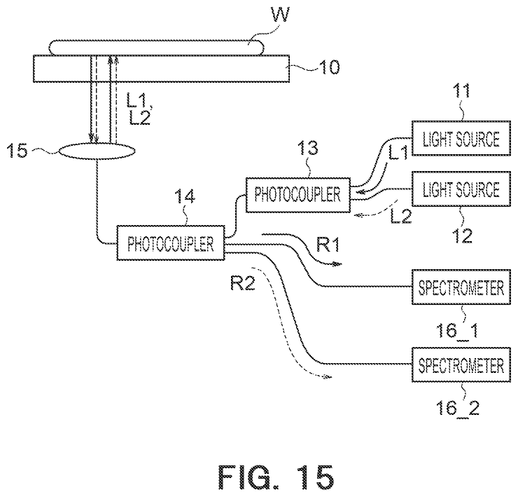

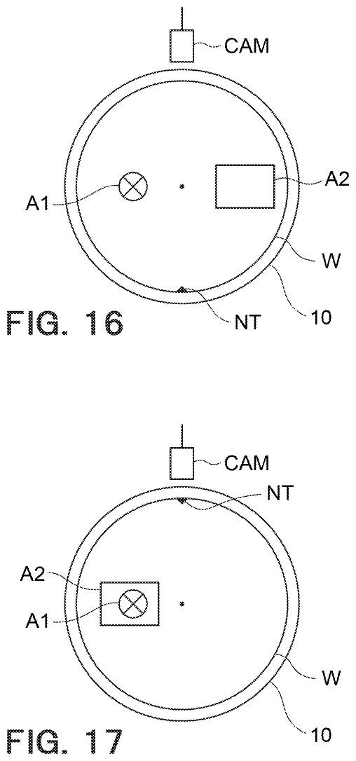

FIGS. 16 and 17 are plan views illustrating a method of obtaining the thickness of (the hole depth in) the substrate W or the material film M according to a second modification.

In a case of obtaining the thickness of (the hole depth in) the substrate W or the material film M, a measurement portion on the substrate W or the material film M is determined. Therefore, the position of the substrate W is adjusted by using information on the arrangement of the substrate W in such a manner that the measurement portion on the substrate W or the material film M is located above a radiated position or radiated positions of the light beams L1 and L2.

For example, the database 18 stores therein the position of a measurement region A2 relative to a notch NT on the substrate W in advance. The database 18 also stores therein the position coordinates of a radiated region A1 of the light beams L1 and L2 on the stage 10 in advance.

A camera CAM that captures an image of the substrate W placed on the stage 10 is provided on the stage 10. It suffices that the camera CAM can capture an image of the substrate W, and the position of the camera CAM is not specifically limited to any position. However, the camera CAM is preferably arranged above the stage 10. The camera CAM is connected to the operation part 17, so that the image of the substrate W is sent to the operation part 17.

The operation part 17 detects the position of the notch NT through image processing of the image of the substrate W and calculates the coordinates of the measurement region A2 on the stage 10 from the position of the measurement region A2 relative to the notch NT. As illustrated in FIG. 16, when the coordinates of the measurement region A2 on the stage 10 and the coordinates of the radiated region A1 do not overlap with each other in plan view as viewed from above the stage 10, the operation part 17 outputs a warning signal indicating this fact. As illustrated in FIG. 17, when the coordinates of the measurement region A2 on the stage 10 and the coordinates of the radiated region A1 overlap with each other in plan view as viewed from above the stage 10, the operation part 17 outputs a permission signal that permits start of processing.

When the warning signal is output, the coordinates of the measurement region A2 and the coordinates of the radiated region A1 are misaligned with each other as illustrated in FIG. 16. Therefore, as illustrated in FIG. 17, a user rotates the substrate W in response to the warning signal to correct the rotational position of the substrate W in such a manner that the coordinates of the measurement region A2 and the coordinates of the radiated region A1 overlap with each other.

When the permission signal is output, the semiconductor manufacturing apparatus 1 starts to process the substrate W and the material film M. The semiconductor manufacturing apparatus 1 can obtain measured spectrum waveforms for the measurement region A2 by radiating the light beams L1 and L2 to the measurement region A2.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor manufacturing apparatus comprising:
a stage configured to support a substrate with a material film on a first face from a second face side of the substrate opposite to the first face;
a light source configured to generate a light beam;
an optical system configured to radiate the light beam to the substrate from the second face side;
a detector configured to detect a reflected light beam reflected from the substrate or the material film;
a storage part configured to store therein a plurality of reference spectrum waveforms respectively generated in advance for a plurality of shape parameters of the substrate or the material film with regard to the reflected light beam; and
an operation part configured to compare a measured spectrum waveform obtained from an interference spectrum of the reflected light beam measured by the detector when the light beam is radiated with each of the reference spectrum waveforms to obtain a similar reference spectrum waveform that is one of the reference spectrum waveforms which is similar to the measured spectrum waveform.

2. The apparatus of claim 1, wherein the operation part calculates Expression 1 or Expression 2 with regard to a light intensity I(x) of the measured spectrum waveform and a light intensity Tⱼ(x) of the each of the reference spectrum waveforms and determines one of the reference spectrum waveforms which provides a maximum correlation value γⱼ(T) as the similar reference spectrum waveform, the Expressions 1 and 2 being
$${r}_{j} ( τ ) = \int I ( x - τ ) {T}_{j} ( x ) dx , and \qquad ( Expression 1 )$$
$${r}_{j} ( τ ) = \int I ( x ) {T}_{j} ( x - τ ) dx , \qquad ( Expression 2 )$$
where x is an optical path length of the light beam, τ is a relative shift amount of wavelength between the measured spectrum waveform and the each of the reference spectrum waveforms, and j is an identifier of the reference spectrum waveforms.

3. The apparatus of claim 2, wherein the operation part calculates a temperature of the substrate or the material film based on the relative shift amount T between the measured spectrum waveform and the similar reference spectrum waveform.

4. The apparatus of claim 2, wherein
the storage part is configured to store therein a relational expression between a shift amount of wavelength and a temperature change amount of the substrate or the material film in advance with regard to the reference spectrum waveforms, and
the operation part is configured to calculate a temperature of the substrate or the material film from the relative shift amount T between the measured spectrum waveform and the similar reference spectrum waveform by using the relational expression.

5. The apparatus of claim 1, wherein the operation part is configured to calculate a processed amount on or in the substrate or the material film based on one of the shape parameters which corresponds to the similar reference spectrum waveform.

6. The apparatus of claim 1, wherein
the light source includes a first light source configured to generate a first light beam with a first wavelength and a second light source configured to generate a second light beam with a second wavelength different from the first wavelength,
the reference spectrum waveforms are generated by linking a plurality of first reference spectrum waveforms generated in advance for the shape parameters of the substrate or the material film with regard to the reflected light beam of the first light beam and a plurality of second reference spectrum waveforms generated in advance for the shape parameters of the substrate or the material film with regard to the reflected light beam of the second light beam together for each substrate or material film having a same shape parameter, and
the measured spectrum waveform is generated by linking a first measured spectrum waveform based on the reflected light beam measured by the detector when the first light beam is radiated to the substrate and a second measured spectrum waveform based on the reflected light beam measured by the detector when the second light beam is radiated to the substrate together.

7. The apparatus of claim 6, wherein the optical system radiates the first light beam and the second light beam to substantially a same position on the substrate.

8. The apparatus of claim 6, wherein the optical system radiates the first light beam and the second light beam to different positions on the substrate.

9. The apparatus of claim 6, wherein the optical system radiates the first light beam and the second light beam to the substrate at substantially a same time.

10. The apparatus of claim 6, wherein
the second light source stops generation of the second light beam while the first light source generates the first light beam, and
the first light source stops generation of the first light beam while the second light source generates the second light beam.

11. The apparatus of claim 1, wherein the shape parameters are any of thicknesses of the substrate or the material film, depths of a hole formed in the substrate or the material film, and diameters of the hole.

12. The apparatus of claim 1, wherein the operation part interpolates another reference spectrum waveform between the shape parameters based on the reference spectrum waveforms for the shape parameters.

13. A semiconductor device manufacturing method using a semiconductor manufacturing apparatus that includes a light source generating a light beam, an optical system radiating the light beam to a substrate with a material film on a first face from a second face side of the substrate opposite to the first face, and a detector detecting a reflected light beam reflected from the substrate or the material film, the method comprising:
generating a plurality of reference spectrum waveforms for a plurality of shape parameters of the substrate or the material film with regard to the reflected light beam in advance;
comparing a measured spectrum waveform of the reflected light beam measured by the detector when the light beam is radiated to the substrate from the second face side with each of the reference spectrum waveforms to obtain a similar reference spectrum waveform that is one of the reference spectrum waveforms which is similar to the measured spectrum waveform; and
calculating a temperature of the substrate or the material film or a processed amount on or in the substrate or the material film based on the similar reference spectrum waveform.

14. The method of claim 13, wherein
the obtaining the similar reference spectrum waveform includes calculating Expression 1 or Expression 2 with regard to a light intensity I(x) of the measured spectrum waveform and a light intensity Tⱼ(x) of the each of the reference spectrum waveforms and determining one of the reference spectrum waveforms which provides a maximum correlation value γrⱼ(T) as the similar reference spectrum waveform, the Expressions 1 and 2 being
$${r}_{j} ( τ ) = \int I ( x - τ ) {T}_{j} ( x ) dx , and \qquad ( Expression 1 )$$
$${r}_{j} ( τ ) = \int I ( x ) {T}_{j} ( x - τ ) dx , \qquad ( Expression 2 )$$
where x is an optical path length of the light beam, τ is a relative shift amount of wavelength between the measured spectrum waveform and the each of the reference spectrum waveforms, and j is an identifier of the reference spectrum waveforms, and
the method comprises calculating the temperature of the substrate or the material film based on the relative shift amount T between the measured spectrum waveform and the similar reference spectrum waveform.

15. The method of claim 14, further comprising:
preparing a relational expression between a shift amount of wavelength and a temperature change amount of the substrate or the material film in advance with regard to the reference spectrum waveforms, wherein the calculating the temperature of the substrate or the material film is performed by using the relative shift amount T and the relational expression.

16. The method of claim 13, wherein the calculating the processed amount on or in the substrate or the material film is performed based on one of the shape parameters which corresponds to the similar reference spectrum waveform.

17. The method of claim 16, wherein the processed amount on or in the substrate or the material film is a processed depth of a hole formed in the substrate or the material film.

18. The method of claim 13, wherein
the light source includes a first light source configured to generate a first light beam with a first wavelength and a second light source configured to generate a second light beam with a second wavelength different from the first wavelength,
the reference spectrum waveforms are generated by linking a plurality of first reference spectrum waveforms generated in advance for the shape parameters of the substrate or the material film with regard to the reflected light beam of the first light beam and a plurality of second reference spectrum waveforms generated in advance for the shape parameters of the substrate or the material film with regard to the reflected light beam of the second light beam together for each substrate or material film having a same shape parameter, and
the measured spectrum waveform is generated by linking a first measured spectrum waveform of the reflected light beam measured by the detector when the first light beam is radiated to the substrate and a second measured spectrum waveform of the reflected light beam measured by the detector when the second light beam is radiated to the substrate together.

19. The method of claim 13, wherein the shape parameters are any of thicknesses of the substrate or the material film, depths of a hole formed in the substrate or the material film, and diameters of the hole.

20. The method of claim 13, further comprising interpolating another reference spectrum waveform between the shape parameters based on the reference spectrum waveforms for the shape parameters.
